(19) United States
(12) Patent Application Publication
(10) Pub. No.: US 2026/0206308 A1
(43) Pub. Date: Jul. 16, 2026

(54) DIELECTRIC STRUCTURE IN TRANSISTOR GATE

(71) Applicant: Samsung Electronics Co., Ltd., Suwon-si (KR)

(72) Inventors: Aravindh Kumar, Mountain View, CA (US); Jaeho Jeon, Gyeonggi-do (KR); Donghoon Hwang, Gyeonggi-do (KR); Youngjin Yang, Gyeonggi-do (KR); Muhammed Ahosan Ul Karim, San Jose, CA (US)

(21) Appl. No.: 19/374,563

(22) Filed: Oct. 30, 2025

Related U.S. Application Data
(60) Provisional application No. 63/745,180, filed on Jan. 14, 2025.

(51) Int. Cl. H10D 84/85; H10D 84/01

(52) U.S. Cl. CPC H10D 84/852; H10D 84/0172; H10D 84/0188

(57) ABSTRACT

A semiconductor device includes a first transistor having a first nanosheet channel region and a source region and a drain region at opposite ends of the first nanosheet channel regions, a second transistor including second nanosheet channel regions and a source region and a drain region at opposite ends of the second nanosheet channel regions, a common gate on the first nanosheet channel regions and the second nanosheet channel regions, and a dielectric layer embedded in the common gate.

### CROSS-REFERENCE TO RELATED APPLICATION(S)

The present application claims priority to and the benefit of U.S. Provisional Application No. 63/745,180, filed Jan. 14, 2025, the entire content of which is incorporated herein by reference.

### BACKGROUND

### 1. Field The present application relates to semiconductor devices and methods of manufacturing the same.

### 2. Description of the Related Art

Semiconductor devices commonly include an n-channel metal-oxide-semiconductor (NMOS) transistor coupled to a −p-channel metal-oxide-semiconductor (PMOS) transistor. Each of the transistors includes a channel region, source/drain regions, contacts on the source/drain regions, and a gate on the channel region.

The above information disclosed in this Background section is only to enhance understanding of background information pertaining to the present disclosure and may contain information that does not constitute prior art.

### SUMMARY

The present disclosure relates to various embodiments of a semiconductor device. In one embodiment, the semiconductor device includes a first transistor having a first nanosheet channel region and a source region and a drain region at opposite ends of the first nanosheet channel regions, a second transistor including second nanosheet channel regions and a source region and a drain region at opposite ends of the second nanosheet channel regions; a common gate on the first nanosheet channel regions and the second nanosheet channel regions, and a dielectric layer embedded in the common gate.

The dielectric layer may have a width in a range from approximately 15 nm to approximately 30 nm.

A lower end of the dielectric structure may be spaced above a lower end of the common gate by a distance in a range from approximately 5 nm to approximately 75 nm.

An outer edge of the dielectric structure may be spaced apart from the first nanosheet channel regions by a distance in a range from approximately 10 nm to approximately 20 nm.

The dielectric structure may include a single layer.

The dielectric structure may include two or more layers.

Each of the first transistor and the second transistor may be a forksheet transistor.

Each of the first transistor and the second transistor may be a gate-all-around transistor.

The dielectric material may have a dielectric constant of approximately 5 or less.

The dielectric material may be silicon dioxide (SiO₂), silicon nitride (SiN), silicon oxycarbonitride (SiOCN), silicon oxynitride (SiON), silicon nitride (SiCN), a metal-organic framework (MOF), or combinations thereof.

The dielectric material may extend substantially entirely across the common gate in a widthwise direction.

The first nanosheet channel regions and the second nanosheet channel regions may have a width of approximately 10-20 nm.

The semiconductor device may include a first dielectric and a second dielectric wall. The first nanosheet channel regions may extend along the first dielectric wall and the second nanosheet channel regions extend along the second dielectric wall.

Each of the first nanosheet channel regions and the second nanosheet channel regions may include from two nanosheets to six nanosheets.

The present disclosure also relates to various embodiments of a method of manufacturing a semiconductor device. In one embodiment, the method includes etching a common gate electrode connecting a first transistor to a second transistor to form a trench in the common gate electrode and substantially filling the trench with a dielectric material.

The method may also include forming a mask prior to the etching of the common gate electrode.

The method may include forming a first forksheet transistor and a second forksheet transistor.

The method may include forming a first gate-all-around transistor and a second gate-all-around transistor.

The dielectric material may have a dielectric constant of approximately 5 or less.

The dielectric material may be silicon dioxide (SiO₂), silicon nitride (SiN), silicon oxycarbonitride (SiOCN), silicon oxynitride (SiON), silicon nitride (SiCN), and/or a metal-organic framework (MOF).

This summary is provided to introduce a selection of features and concepts of embodiments of the present disclosure that are further described below in the detailed description. This summary is not intended to identify key or essential features of the claimed subject matter, nor is it intended to be used in limiting the scope of the claimed subject matter. One or more of the described features may be combined with one or more other described features to provide a workable semiconductor device or a method of manufacturing a semiconductor device.

### BRIEF DESCRIPTION OF THE DRAWINGS

The features and advantages of embodiments of the present disclosure will become more apparent by reference to the following detailed description when considered in conjunction with the following drawings. In the drawings, like reference numerals are used throughout the figures to reference like features and components. The figures are not necessarily drawn to scale.

FIG. 1A is a front perspective view of a semiconductor device according to one embodiment of the present disclosure;

FIG. 1B is a rear perspective view of the semiconductor device of FIG. 1A according to one embodiment of the present disclosure;

FIG. 1C is a side perspective view of the semiconductor device of FIG. 1A according to one embodiment of the present disclosure;

FIG. 1D is a top view of the semiconductor device of FIG. 1A according to one embodiment of the present disclosure;

FIG. 1E is a first cross-sectional view of the semiconductor device of FIG. 1A according to one embodiment of the present disclosure;

FIG. 1F is a second cross-sectional view of the semiconductor device of FIG. 1A according to one embodiment of the present disclosure;

FIG. 2A is a perspective view of a semiconductor device according to another embodiment of the present disclosure including gate-all-around (GAA) transistors;

FIG. 2B is a top view of the semiconductor device of FIG. 2A according to one embodiment of the present disclosure;

FIG. 2C is a first cross-sectional view of the semiconductor device of FIG. 2A according to one embodiment of the present disclosure;

FIG. 2D is a second cross-sectional view of the semiconductor device of FIG. 2A according to one embodiment of the present disclosure;

FIG. 3 is a flowchart illustrating tasks of manufacturing a semiconductor device according to one embodiment of the present disclosure;

FIGS. 4A-4D are cross-sectional views illustrating aspects of manufacturing a semiconductor device according to one embodiment of the present disclosure;

FIG. 5 is a schematic block diagram of an electronic device including a semiconductor device according to one embodiment of the present disclosure;

FIG. 6 is a bar chart comparing the middle-of-line (MOL) layer capacitance for a related art semiconductor device to a semiconductor device according to one embodiment of the present disclosure including a dielectric structure;

FIG. 7A is a graph depicting the reduction in MOL capacitance as a function of the distance between the dielectric structure and the bottom of the common gate according to one embodiment of the present disclosure;

FIG. 7B is a graph depicting the reduction in power at isolation frequency as a function of the distance between the dielectric structure and the bottom of the common gate according to one embodiment of the present disclosure;

FIG. 8A is a graph depicting the components of a semiconductor device that contribute to MOL input capacitance; and

FIG. 8B is a graph depicting the components of a semiconductor device that contribute to MOL output capacitance.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The advancement of semiconductor technology continues to drive the need for transistor architectures that support increased device density, enhanced performance, and reduced power consumption at progressively smaller technology nodes. As process geometries scale, transistor designs incorporating gate structures that provide improved electrostatic control over the channel region may be utilized to address challenges associated with short-channel effects, leakage currents, and overall device reliability.

Transistor architectures utilized stacked channel structures and gate-all-around configurations may be utilized to facilitate improved control and scalability. In certain designs, isolation features may be positioned between adjacent devices to enable tighter integration of complementary transistors while maintaining electrical isolation and optimizing gate pitch.

As semiconductor devices evolve toward more advanced nodes, various design considerations arise, including minimizing or reducing parasitic capacitance, ensuring precise gate alignment, managing variability in channel structures, and simplifying fabrication processes.

The present disclosure relates to various embodiments of a semiconductor device including a dielectric material in a common gate connecting an NMOS transistor to a PMOS transistor. In semiconductor devices, a central portion of the gate metal between the NMOS and PMOS transistors is not necessary to couple the transistor to each other and this central portion of the gate metal is coupled to source/drain contacts, which increases the parasitic capacitance and the power consumption of the semiconductor device. The dielectric material is configured to reduce the parasitic capacitance caused by the coupling between the common gate and the source/drain contacts of the semiconductor device. Reducing the coupling between the common gate and the source/drain contacts of the semiconductor device by providing a dielectric structure in the common gate reduces the middle-of-line (MOL) capacitance of the semiconductor device, which contributes the most to the overall capacitance of the semiconductor device. Additionally, reducing the parasitic capacitance is configured to reduce the power consumption of the semiconductor device compared to an otherwise comparable semiconductor device without the dielectric material in the common gate.

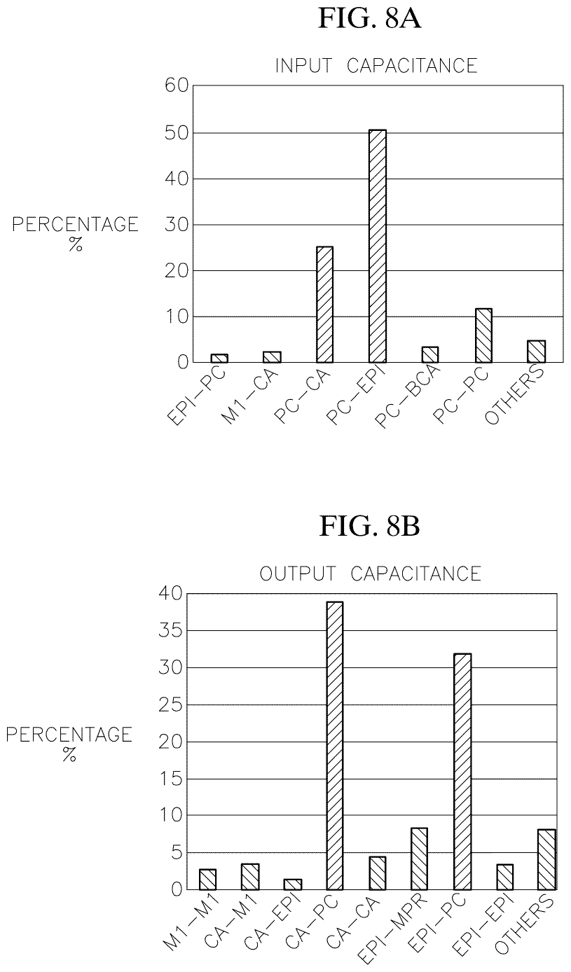

FIG. 8A shows that the capacitance between the gate and the source/drain regions (“PC-EPI”) and the capacitance between the gate and the source/drain contacts (“PC-CA”) contribute the most to the overall MOL input capacitance of the semiconductor device (i.e., gate-source/drain capacitance contributes about 50% and gate-source/drain contact capacitance contributes about 25% to the overall MOL input capacitance). Additionally, FIG. 8B shows that the capacitance between the gate and the source/drain regions (“PC-EPI”) and the capacitance between the gate and the source/drain contact (“PC-CA”) contribute the most to MOL output capacitance (i.e., gate-source/drain capacitance contributes about 31% and gate-source/drain contact capacitance contributes about 36% to the overall MOL output capacitance). Additionally, MOL capacitance contributes about 59% of the overall capacitance of the semiconductor device (i.e., MOL capacitance contributes about 59% and front-end-of-line (FEOL) contributes about 41% of the overall capacitance of the semiconductor device). Accordingly, reducing the coupling between the common gate and the source/drain contacts of the semiconductor device by providing a dielectric structure in the common gate reduces the MOL capacitance, which in turn reduces the overall capacitance of the semiconductor device.

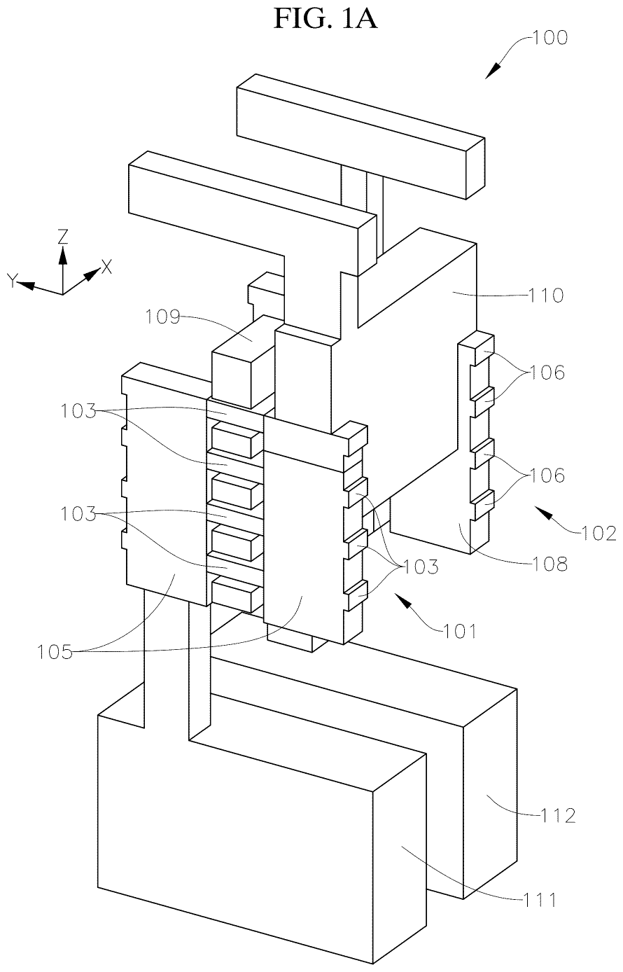

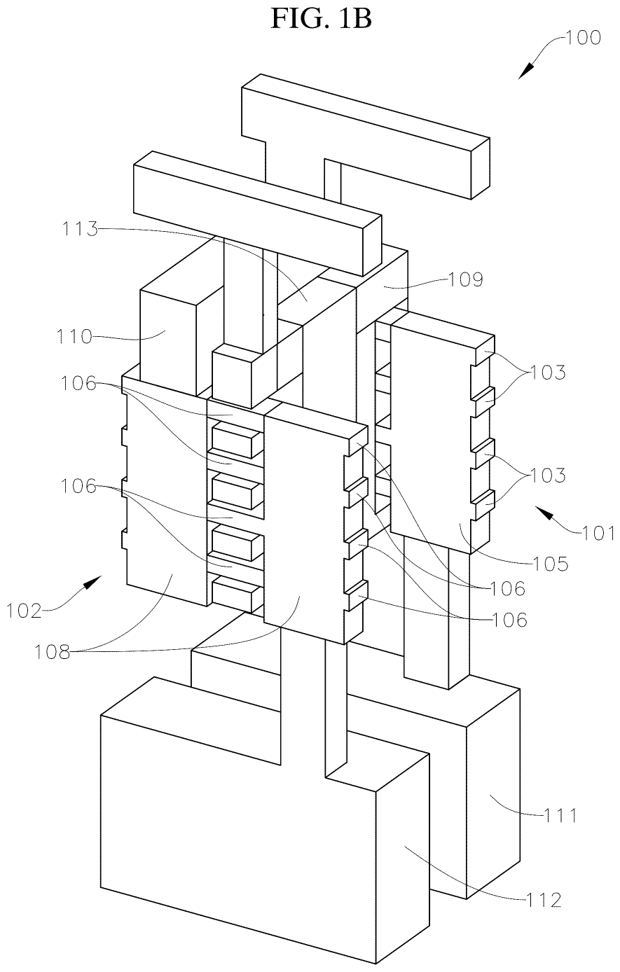

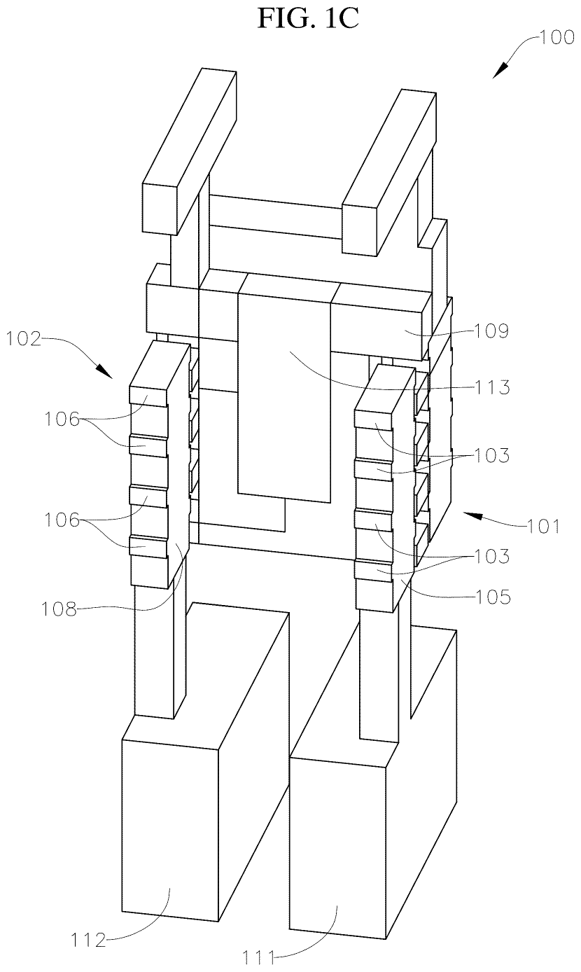

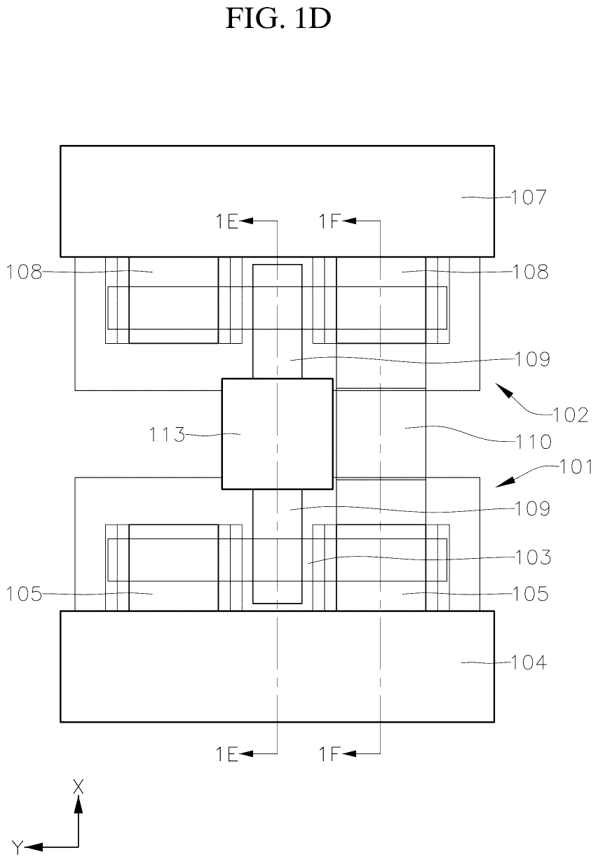

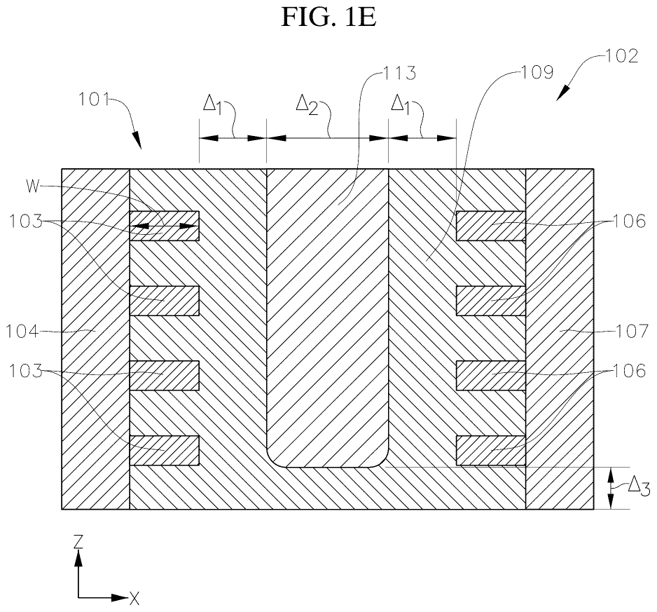

FIG. 1A is a front perspective view of a semiconductor device 100 according to one embodiment of the present disclosure. FIG. 1B is a rear perspective view of the semiconductor device 100 of FIG. 1A. FIG. 1C is a side perspective view of the semiconductor device 100 of FIG. 1A. FIG. 1D is a top view of the semiconductor device 100 of FIG. 1A. FIG. 1E is a first cross-sectional view of the semiconductor device 100 of FIG. 1A. FIG. 1F is a second cross-sectional view of the semiconductor device 100 of FIG. 1A. With reference now to FIGS. 1A-1D, a semiconductor device 100 (e.g., a MOSFET circuit) according to one embodiment of the present disclosure includes a first transistor 101 and a second transistor 102 coupled to each other. In one or more embodiments, the first transistor 101 may be an n-channel metal-oxide-semiconductor (NMOS) transistor and the second transistor 102 may be a p-channel metal-oxide-semiconductor (PMOS) transistor, or the first transistor 101 may be a PMOS transistor 101 and the second transistor 102 may be an NMOS transistor. The first transistor 101 includes a first plurality of nanosheet channel regions 103 extending lengthwise in a first direction (y-axis direction) along a first dielectric wall 104 and source/drain regions 105 at opposite ends of the first plurality of nanosheet channel regions 103. The second transistor 102 includes a second plurality of nanosheet channel regions 106 extending lengthwise in the first direction (y-axis direction) along a second dielectric wall 107 and source/drain regions 108 at opposite ends of the second plurality of nanosheet channel regions 106. Although in the illustrated embodiment each of the first and second transistors 101, 102 includes four nanosheet channel regions 103, 106, respectively, in one or more embodiments the first and second transistors 101, 102 may include any other suitable number of nanosheet channel regions, such as from two to six nanosheet channel regions. In one or more embodiments, the width W of the nanosheet channel regions 103, 106 may be in a range from approximately 8 nm to approximately 20 nm (e.g., the width of the nanosheets may be approximately 10 nm). However, the present disclosure is not limited thereto and in one or more embodiments the nanosheet channel regions 103, 106 may have any other suitable width W.

In the illustrated embodiment, the semiconductor device 100 also includes a common gate 109 on the first plurality of nanosheet channel regions 103 of the first transistor 101 and the second plurality of nanosheet channel regions 106 of the second transistor 102 (e.g., the common gate 109 extends between adjacent nanosheet channel regions, below the lowermost nanosheet channel region, and above the uppermost nanosheet channel region for each of the first and second plurality of nanosheet channel regions 103, 106).

In the illustrated embodiment, the semiconductor device 100 also includes a source/drain contact 110 coupled to the source/drain regions 105, 108 of the first and second transistors 101, 102, a negative supply voltage line (VSS) 111 coupled to a source terminal of the first transistor 101, and a positive drain supply voltage line (VDD) 112 coupled to a drain terminal of the second transistor 102.

The semiconductor device also includes a dielectric structure (or dielectric layer(s)) 113 in (e.g., embedded in) the common gate 109. The dielectric structure 113 extends downward in the z-axis direction through the thickness of the common gate 109, lengthwise along the common gate 109 in the y-axis direction, and widthwise across the common gate 109 in the x-axis direction. In one or more embodiments, the dielectric structure 113 may include a single layer or two or more layers of a dielectric material. In one or more embodiments, the dielectric structure 113 may have a dielectric constant k less than approximately 5.0. As described in more detail below, the dielectric structure 113 having a dielectric constant k less than approximately 5.0 is configured to electrically decouple (or at least reduce the electrical coupling) between the common gate 109 and the source/drain contacts 110 of the semiconductor device 100, thereby reducing the parasitic capacitance of the semiconductor device 100 and reducing the power consumption of the semiconductor device 100 compared to an otherwise comparable semiconductor device without the dielectric material in the common gate. In one or more embodiments, the dielectric structure 113 may have a dielectric constant k in a range from approximately 3.0 to approximately 5.0 (e.g., the dielectric structure 113 may have a dielectric constant k of approximately 3.9). In one or more embodiments, the dielectric structure 113 may be formed from (or include) silicon dioxide (SiO₂), silicon nitride (SiN), silicon oxycarbonitride (SiOCN), silicon oxynitride (SiON), silicon nitride (SiCN), a metal-organic framework (MOF), or any combination thereof. Suitable MOFs are described in Cao et al., “Atomic Regulation of Metal-Organic Framework Thin Film for Low-K Dielectric,” Chemistry of Materials 2024, 36 (22), 11160-11169, available online at https://doi.org/10.1021/acs.chemmater.4c02057, the entire content of which is incorporated herein by reference.

Additionally, in the illustrated embodiment, the dielectric structure 113 does not extend completely through the entirety of the common gate 109 in the z-axis direction such that a lower end portion of common gate 109 remains below the dielectric structure 113, which maintains the electrical connection between the first and second transistors 101, 102. Outer edges of the dielectric structure 113 are spaced apart from the nanosheet channel regions of the first and second plurality of nanosheet channel regions 103, 106 by a threshold distance Δ₁ (i.e., lateral spacing distance). In one or more embodiments, lateral spacing distance Δ₁ may be in a range from approximately 10 nm to approximately 20 nm (e.g., lateral spacing distance Δ₁ may be in a range from approximately 15 nm to approximately 20 nm). The dielectric structure 113 has a width Δ₂. In one or more embodiments, the width Δ₂ of the dielectric structure 113 may be in a range from approximately 15 nm to approximately 30 nm (e.g., the width Δ₂ of the dielectric structure 113 may be in a range from approximately 20 nm to approximately 25 nm). The dielectric structure 113 is spaced apart from a lower end of the common gate 109 by a threshold distance Δ₃ (i.e., vertical spacing distance). In one or more embodiments, the vertical spacing distance Δ₃ from the lower end of the dielectric structure 113 to the lower ends of the common gate 109 may be in a range from approximately 5 nm to approximately 75 nm (e.g., the vertical spacing distance Δ₃ may be in a range from approximately 45 nm to approximately 60 nm). The present disclosure is not limited to the values described above, and the lateral spacing distanceΔ₁ that the outer edges of the dielectric structure 113 are spaced apart from the nanosheet channel regions, the width Δ₂ of the dielectric structure 113, and the vertical spacing distance Δ₃ from the lower end of the dielectric structure 113 to the lower ends of the common gate 109 may be any other suitable values. For instance, in one or more embodiments, the lateral spacing distance Δ₁ may be less than 10 nm or greater than 20 nm, the width Δ₂ of the dielectric structure 113 may be less than 15 nm or greater than 30 nm, and the vertical spacing distance Δ₃ may be less than 5 nm or greater than 75 nm.

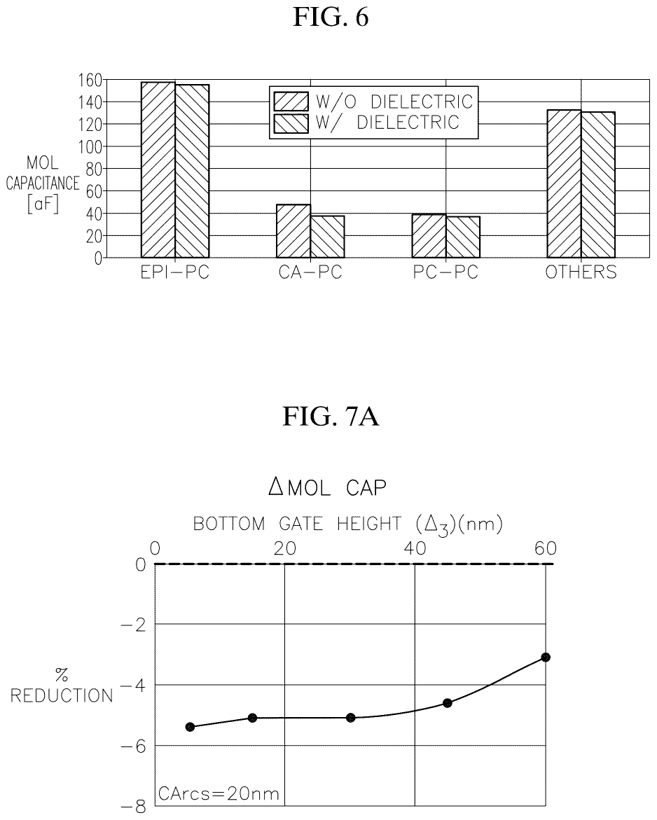

The dielectric structure 113 is configured to reduce the coupling between the common gate 109 and the source/drain contact 110, in order to reduce the parasitic capacitance of the semiconductor device 100 and reduce the power consumption of the semiconductor device 100. For instance, FIG. 6 is a bar chart comparing the middle-of-line (MOL) layer capacitance for a related art semiconductor device to the semiconductor device 100 according to one embodiment of the present disclosure including a dielectric structure 113 in which the vertical spacing distance Δ₃ from the lower end of the dielectric structure 113 to the lower ends of the common gate 109 is approximately 5.4 nm. As illustrated in FIG. 6, the MOL capacitance between the gate and the source/drain contacts for the related art semiconductor device is approximately 48 attofarad (aF), whereas the MOL capacitance between the gate and the source/drain contacts for the the semiconductor device 100 according to one embodiment of the present disclosure is approximately 38 aF. Accordingly, as shown in FIG. 6, the dielectric structure 113 in one embodiment is configured to reduce the parasitic capacitance between the gate and the source/drain contacts by approximately 10aF compared to a related art semiconductor device without the dielectric structure in the common gate.

FIG. 6 also compares the MOL capacitance for a related art semiconductor device to the semiconductor device 100 according to one embodiment of the present disclosure including a dielectric structure 113 in which the width Δ₂ of the dielectric structure 113 approximately 25 nm. As illustrated in FIG. 6, the MOL capacitance between the gate and the source/drain regions for the related art semiconductor device is approximately 159 aF, whereas the MOL capacitance between the gate and the source/drain regions for the semiconductor device 100 according to one embodiment of the present disclosure is approximately 157 aF. Accordingly, as shown in FIG. 6, the dielectric structure 113 in one embodiment is configured to reduce the parasitic capacitance between the gate and the source/drain regions by approximately 2 aF compared to a related art semiconductor device without the dielectric structure in the common gate.

FIG. 6 also depicts that the gate to gate MOL capacitance is less for the semiconductor device 100 according to the present embodiment compared to a related art semiconductor device without the dielectric structure in the common gate.

For instance, a semiconductor device 100 according to one embodiment of the present disclosure in which the width Δ₂ of the dielectric structure 113 is approximately 20 nm and the vertical spacing distance Δ₃ from the lower end of the dielectric structure 113 to the lower ends of the common gate 109 is approximately 45 nm may exhibit an approximately 3.1% reduction in MOL capacitance, an approximately 4% reduction in power at isolation frequency, and approximately a 1.2% reduction in frequency at power compared to a related art semiconductor device without the dielectric structure in the common gate. In one or more embodiments, a semiconductor device 100 according to one embodiment of the present disclosure in which the width Δ₂ of the dielectric structure 113 is approximately 20 nm and the vertical spacing distance Δ₃ from the lower end of the dielectric structure 113 to the lower ends of the common gate 109 is approximately 60 nm may exhibit an approximately 2.9% reduction in MOL capacitance, an approximately 3.7% reduction in power at isolation frequency, and approximately a 1.1% reduction in frequency at power compared to a related art semiconductor device without the dielectric structure in the common gate. In one or more embodiments, a semiconductor device 100 according to one embodiment of the present disclosure in which the width Δ₂ of the dielectric structure 113 is approximately 25 nm and the vertical spacing distance Δ₃ from the lower end of the dielectric structure 113 to the lower ends of the common gate 109 is approximately 45 nm may exhibit an approximately 4.6% reduction in MOL capacitance, an approximately 5.7% reduction in power at isolation frequency, and approximately a 1.7% reduction in frequency at power compared to a related art semiconductor device without the dielectric structure in the common gate. In one or more embodiments, a semiconductor device 100 according to one embodiment of the present disclosure in which the width Δ₂ of the dielectric structure 113 is approximately 25 nm and the vertical spacing distance Δ₃ from the lower end of the dielectric structure 113 to the lower ends of the common gate 109 is approximately 60 nm may exhibit an approximately 3.1% reduction in MOL capacitance, an approximately 4.1% reduction in power at isolation frequency, and approximately a 1.2% reduction in frequency at power compared to a related art semiconductor device without the dielectric structure in the common gate. Accordingly, in one or more embodiments, an approximately 4% reduction in power at isolation frequency may be achieved by providing a relatively shallow and narrow dielectric structure in the common gate, such as, for example, a dielectric structure having a width in a range from approximately 20 nm to approximately 25 nm and being spaced above the lower end of the common gate by approximately 60 nm.

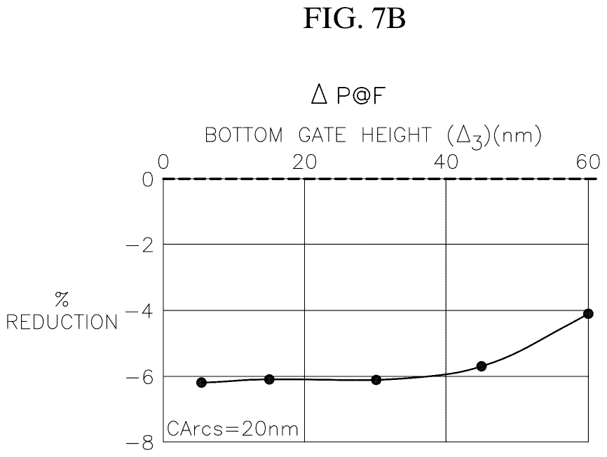

FIG. 7A is a graph depicting the reduction in MOL capacitance (“Δ MOL Cap”) as a function of the vertical spacing distance Δ₃ from the lower end of the dielectric structure 113 to the lower end of the common gate 109 according to one embodiment of the present disclosure; FIG. 7A depicts the MOL capacitance for an embodiment of the semiconductor device 100 in which the width Δ₂ of the dielectric structure 113 is approximately 25 nm and in which the source/drain contact 110 have a height of approximately 20 nm. In FIG. 7A, the solid line depicts the MOL capacitance for the semiconductor device according to embodiments of the present disclosure and the dashed line depicts the MOL capacitance for a related art semiconductor device without the dielectric structure in the common gate. As illustrated in FIG. 7A, the reduction in MOL capacitance becomes greater by reducing the vertical spacing distance Δ₃ from the lower end of the dielectric structure 113 to the lower end of the common gate 109 (i.e., increasing the height of the dielectric structure 113) and the benefits saturate at around 30 nm (i.e., there are no further benefits, or only marginal additional benefits, in MOL capacitance reduction by reducing the vertical spacing distance Δ₃ below 30 nm).

FIG. 7B is a graph depicting the reduction in power at isolation frequency (“ΔP@F”) as a function of the vertical spacing distance Δ₃ from the lower end of the dielectric structure 113 to the lower end of the common gate 109 according to one embodiment of the present disclosure; FIG. 7A depicts the power at isolation frequency for an embodiment of the semiconductor device 100 in which the width Δ₂ of the dielectric structure 113 is approximately 25 nm and in which the source/drain contact 110 have a height of approximately 20 nm. In FIG. 7B, the solid line depicts the MOL capacitance for the semiconductor device according to embodiments of the present disclosure and the dashed line depicts the MOL capacitance for a related art semiconductor device without the dielectric structure in the common gate. As illustrated in FIG. 7B, the reduction in power at isolation frequency becomes greater by reducing the vertical spacing distance Δ₃ from the lower end of the dielectric structure 113 to the lower end of the common gate 109 (i.e., increasing the height of the dielectric structure 113) and the benefits saturate at around 30 nm (i.e., there are no further benefits, or only marginal additional benefits, in power at isolation frequency reduction by reducing the vertical spacing distance Δ₃ below 30 nm). Additionally, as illustrated in FIG. 7B, the power at isolation frequency for an embodiment of the semiconductor device 100 the vertical spacing distance Δ₃ is approximately 5.4 nm is reduced by approximately 6.2% compared to a related art semiconductor device without the dielectric structure in the common gate.

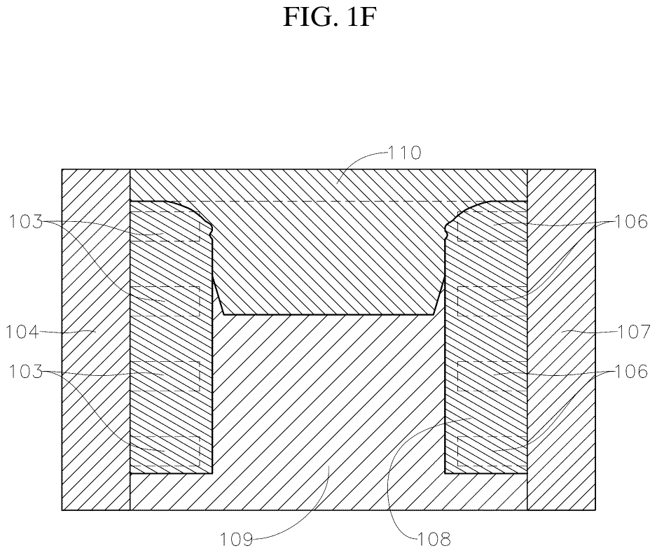

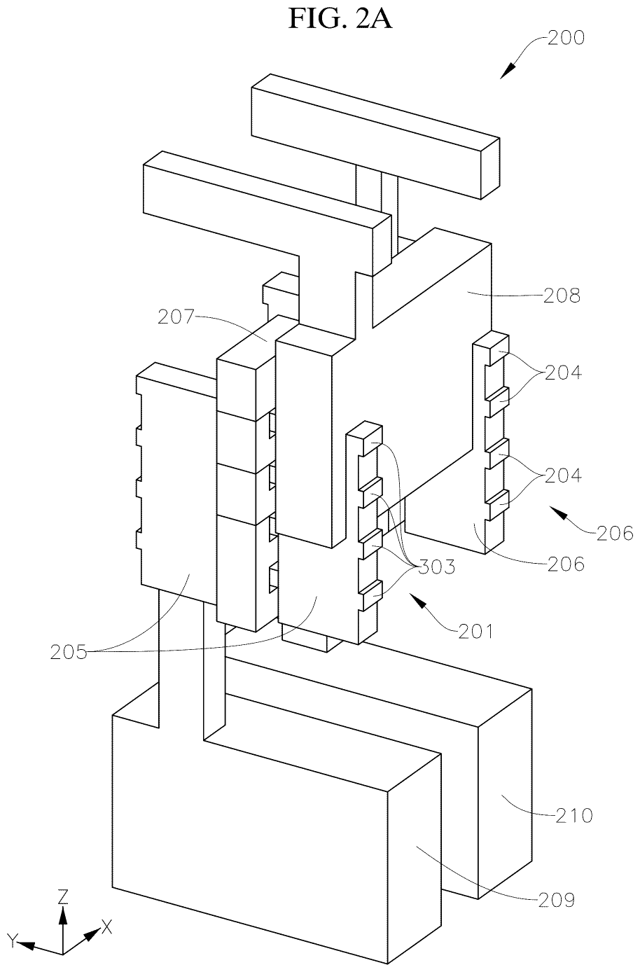

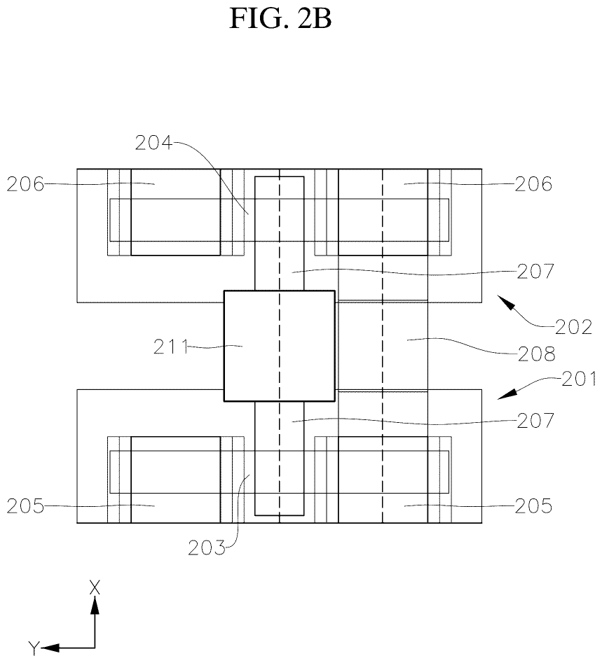

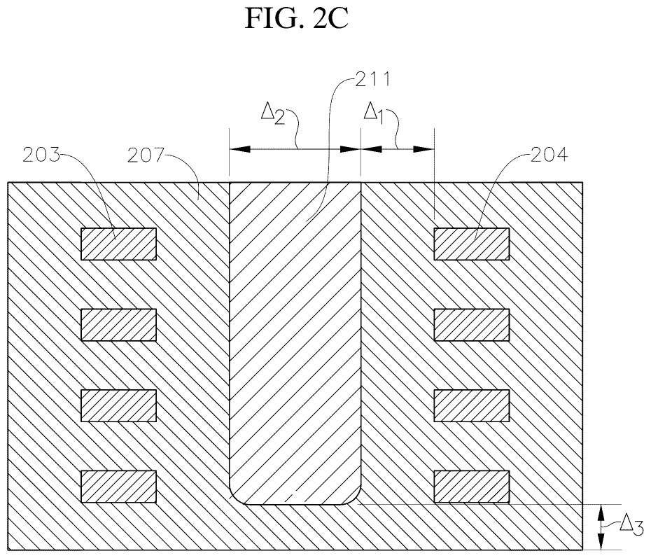

Although in the embodiment illustrated in FIGS. 1A-1D the first and second transistors 101, 102 are forksheet FETs (i.e., the first plurality of nanosheet channel regions 103 extend outward from the first dielectric wall 104, and the second plurality of nanosheet channel regions 106 extend outward from the second dielectric wall 107), in one or more embodiments, the first and second transistors 101, 102 may be any other suitable type or kind of transistors. For instance, FIGS. 2A-2D illustrate a semiconductor device 200 according to another embodiment of the present disclosure including a first gate-all-around (GAA) transistor 201 and a second GAA transistor 202 coupled to the first GAA transistor 201. FIG. 2A is a perspective view of the semiconductor device 200. FIG. 2B is a top view of the semiconductor device 200 of FIG. 2A. FIG. 2C is a first cross-sectional view of the semiconductor device 200 of FIG. 2A. FIG. 2D is a second cross-sectional view of the semiconductor device 200 of FIG. 2A. In one or more embodiments, the first GAA transistor 201 may be an NMOS transistor and the second GAA transistor 202 may be a PMOS transistor, or the first GAA transistor 201 may be a PMOS transistor and the second GAA transistor 202 may be an NMOS transistor. Each of the first and second GAA transistors 201, 202 includes a plurality of nanosheet channel regions 203, 204 extending lengthwise in a first direction (y-axis direction) and source/drain regions 205, 206 at opposite ends of the plurality of nanosheet channel regions 203, 204, respectively. Although in the illustrated embodiment each of the first and second GAA transistors 201, 202 includes four nanosheet channel regions 203, 204, respectively, in one or more embodiments the first and second GAA transistors 201, 202 may include any other suitable number of nanosheet channel regions, such as from two to six nanosheet channel regions. In one or more embodiments, the width of the nanosheets channel regions 203, 204 may be in a range from approximately 8 nm to approximately 12 nm (e.g., the width of the nanosheets may be approximately 10 nm).

In the illustrated embodiment, the semiconductor device 200 also includes a common gate 207 on the nanosheet channel regions 203, 204 of the first and second GAA transistors 201, 202 (e.g., the common gate 207 extends between adjacent nanosheet channel regions, below the lowermost nanosheet channel region, and above the uppermost nanosheet channel region for each of the nanosheet channel regions 203, 204).

In the illustrated embodiment, the semiconductor device 200 also includes a source/drain contact 208 coupled to the source/drain regions 205, 206 of the first and second GAA transistors 201, 202, a negative supply voltage line (VSS) 209 coupled to a source terminal of the first GAA transistor 201, and a positive drain supply voltage line (VDD) 210 coupled to a drain terminal of the second GAA transistor 202.

The semiconductor device 200 also includes a dielectric layer 211 in (e.g., embedded in) the common gate 207. The dielectric layer 211 extends downward in the z-axis direction through the thickness of the common gate 207, lengthwise along the common gate 207 in the y-axis direction, and widthwise across the common gate 207 in the x-axis direction. In one or more embodiments, the dielectric layer 211 may have any suitably low dielectric constant k such that the dielectric layer 211 functions as an insulator. For instance, the dielectric layer 211 may have a dielectric constant k less than a threshold value (e.g., less than approximately 5.0). In one or more embodiments, the dielectric layer 211 may have a dielectric constant k in a range from approximately 3.0 to approximately 5.0 (e.g., the dielectric layer 211 may have a dielectric constant k of approximately 3.9). In one or more embodiments, the dielectric layer 211 may be formed from (or include) silicon dioxide (SiO₂), silicon nitride (SiN), silicon oxycarbonitride (SiOCN), silicon oxynitride (SiON), silicon nitride (SiCN), a metal-organic framework (MOF), or any combination thereof.

Additionally, in the illustrated embodiment, the dielectric layer 211 does not extend completely through the entirety of the common gate 207 in the z-axis direction such that a lower end portion of common gate 207 remains below the dielectric layer 211, which maintains the electrical connection between the first and second GAA transistors 201, 202. Outer edges of the dielectric layer 211 are spaced apart from the nanosheet channel regions of the first and second plurality of nanosheet channel regions 203, 204 by a threshold distance Δ₁ (i.e., lateral spacing distance). In one or more embodiments, the lateral spacing distance Δ₁ may be in a range from approximately 10 nm to approximately 20 nm (e.g., the lateral spacing distance Δ₁ may be in a range from approximately 15 nm to approximately 20 nm). The dielectric layer 211 has a width Δ₂. In one or more embodiments, the width Δ₂ of the dielectric layer 211 may be in a range from approximately 15 nm to approximately 30 nm (e.g., the width Δ₂ of the dielectric layer 211 may be in a range from approximately 20 nm to approximately 25 nm). The dielectric layer 211 is spaced apart from a lower end of the common gate 207 by a threshold distance Δ₃ (i.e., vertical spacing distance). In one or more embodiments, the vertical spacing distance Δ₃ from the lower end of the dielectric layer 211 to the lower end of the common gate 207 may be in a range from approximately 5 nm to approximately 75 nm (e.g., the vertical spacing distance Δ₃ may be in a range from approximately 45 nm to approximately 60 nm). The present disclosure is not limited to the values described above, and the lateral spacing distance Δ₁ that the outer edges of the dielectric structure 211 are spaced apart from the nanosheet channel regions, the width Δ₂ of the dielectric layer 211, and the vertical spacing distance Δ₃ from the lower end of the dielectric layer 211 to the lower ends of the common gate 207 may be any other suitable values. For instance, in one or more embodiments, lateral spacing distance Δ₁ may be less than 10 nm or greater than 20 nm, the width Δ₂ of the dielectric structure 211 may be less than 15 nm or greater than 30 nm, and the vertical spacing distance Δ₃ may be less than 5 nm or greater than 75 nm.

The semiconductor device 200 may be the same as the semiconductor device 100 illustrated in FIGS. 1A-1E except that it does not include the first and second dielectric walls 104, 107 and the common gate 207 completely surrounds the nanosheet channel regions 203, 204 (i.e., the common gate 207 surrounds all four sides of each of the nanosheet channel regions 203, 204). That is, unlike the semiconductor device 100, the semiconductor device 200 does not include the first and second dielectric walls 104, 107 and the common gate 207 completely surrounds the nanosheet channel regions 203, 204 because it includes different types of transistors, namely, GAAs rather than forksheet FETs as illustrated in FIGS. 1A-1F.

The dielectric layer 211 is configured to reduce the coupling between the common gate 207 and the source/drain contact 208, which is configured to reduce the parasitic capacitance of the semiconductor device 200 and reduce the power consumption of the semiconductor device 200.

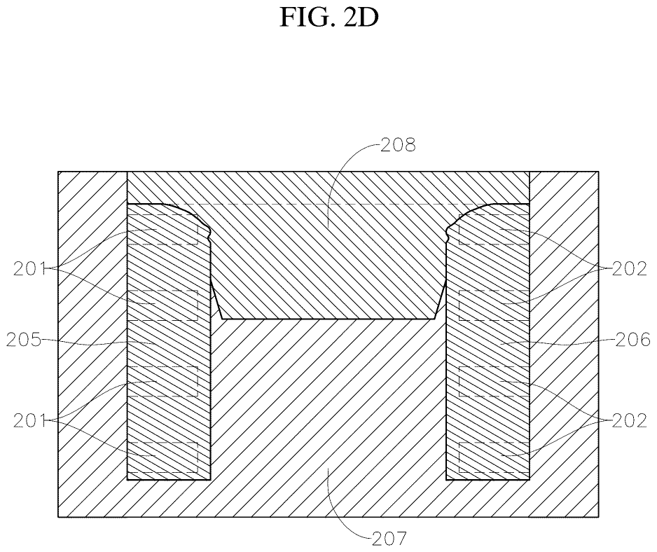

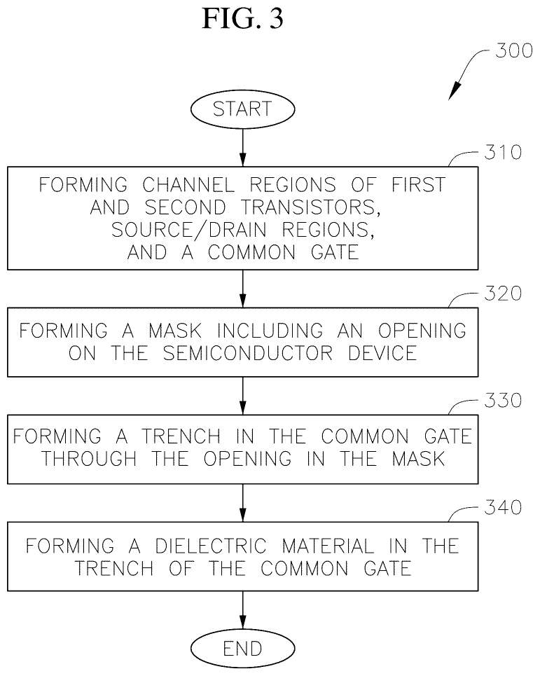

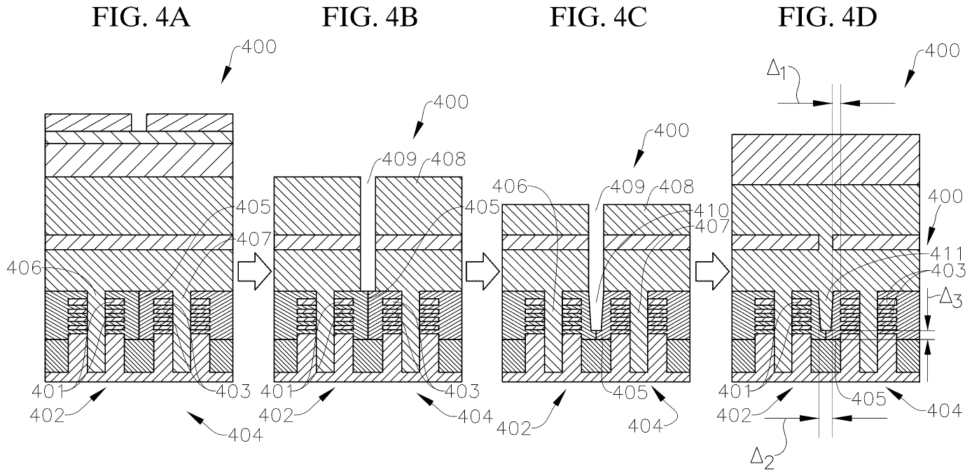

FIG. 3 is a flowchart illustrating aspects of a method 300 of manufacturing a semiconductor device 400 according to one embodiment of the present disclosure. In one or more embodiments, the method 300 includes a task 310 of forming or obtaining a semiconductor device 400 including a channel region 401 (e.g., nanosheet channel regions) of a first transistor 402, a channel region 403 (e.g., nanosheet channel regions) of a second transistor 404, source/drain regions at the ends of the channel regions 401, 403, and a common gate 405 on the channel regions 401, 403 of the first and second transistors 402, 404. In the illustrated embodiment, the first and second transistors 402, 404 are forksheet transistors that extend from dielectric walls 406, 407, respectively, separating the semiconductor device 400 from adjacent semiconductor devices. FIG. 4A depicts the semiconductor device 400 after full gate metallization, which includes the formation of the common gate on the nanosheet channel regions 401, 403 of the first and second transistors 402, 404.

In the illustrated embodiment, the method 300 also includes a task 320 of forming (e.g., depositing) a mask 408 on top of the semiconductor device 400. The mask 408 includes an opening 49 aligned or substantially aligned with the common gate 405 of the semiconductor device 400.

In the illustrated embodiment, the method 300 includes a task 330 of forming (e.g., etching) a trench 410 in the common gate 405 through the mask 409 formed in task 320. FIG. 4C depicts the formation of the trench 410 in the common gate 405. As illustrated in FIG. 4C, the trench 410 does not extend completely through the entirety of the common gate 405 such that a portion of the common gate 405 remains below the trench 410. This portion of the common gate 405 that remains below the trench 410 is configured to electrically connect the first and second transistors 402, 404 to each other.

In the illustrated embodiment, the method 300 includes a task 340 of forming (e.g., depositing) a dielectric material 411 in the trench 410 formed in task 330. In one or more embodiments, the dielectric material 411 may have a dielectric constant k less than approximately 5.0. In one or more embodiments, the dielectric material 411 may have a dielectric constant k in a range from approximately 3.0 to approximately 5.0 (e.g., the dielectric material 411 may have a dielectric constant k of approximately 3.9). In one or more embodiments, the dielectric material 411 may be (or include) silicon dioxide (SiO₂), silicon nitride (SiN), silicon oxycarbonitride (SiOCN), silicon oxynitride (SiON), silicon nitride (SiCN), a metal-organic framework (MOF), or any combination thereof.

In one or more embodiments, the trench 410 formed in task 330 may be configured (sized and shaped) such that outer edges of the dielectric material 411 deposited in task 340 are spaced apart from the nanosheet channel regions 401, 403 of the first and second transistors 402, 404 by a lateral spacing distance Δ₁. In one or more embodiments, the lateral spacing distance Δ₁ may be in a range from approximately 10 nm to approximately 20 nm (e.g., the lateral spacing distance Δ₁ may be in a range from approximately 15 nm to approximately 20 nm). In one or more embodiments, the trench 410 formed in task 330 may be configured (sized and shaped) such that the width Δ₂ of the dielectric material 411 deposited in task 340 may be in a range from approximately 15 nm to approximately 30 nm (e.g., the width Δ₂ of the dielectric material 411 may be in a range from approximately 20 nm to approximately 25 nm). The dielectric material 411 is spaced apart from a lower end of the common gate 405 by a vertical spacing distance Δ₃. In one or more embodiments, the trench 410 formed in task 330 may be configured (sized and shaped) such that the vertical spacing distance Δ₃ from the lower end of the dielectric material 411 deposited in task 340 to the lower end of the common gate 405 may be in a range from approximately 5 nm to approximately 75 nm (e.g., the vertical spacing distance Δ₃ may be in a range from approximately 45 nm to approximately 60 nm).

Although the method 300 depicted in FIGS. 3 and 4A-4D is utilized to form a semiconductor device including forksheet FETs, it will be appreciated that the same steps may be utilized to form any other suitable type or kind of semiconductor device, such as a semiconductor device including gate-all-around (GAA) transistors.

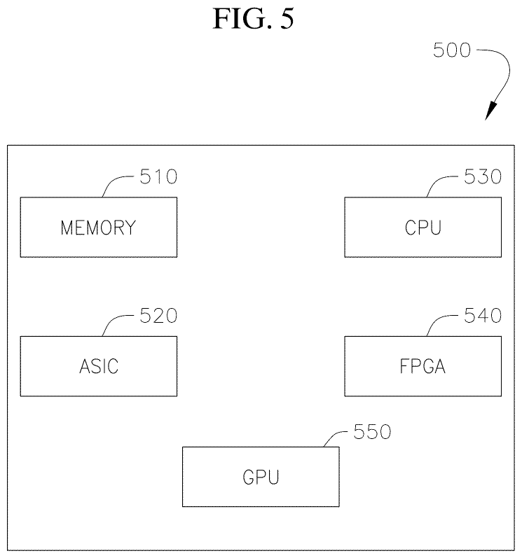

FIG. 5 depicts an electronic device 500 including a semiconductor device (e.g., the semiconductor 100, 200 of FIGS. 1A-1F or 2A-2D or the semiconductor device 400 manufactured according to the method 300 of FIG. 3) according to one embodiment of the present disclosure. Referring to FIG. 5, the electronic device 500 may include at least one of a memory 510, an application specific integrated circuit (ASIC) 520, a central processing unit (CPU) 530, a field programmable gate array (FPGA) 540, or a graphics processing unit (GPU) 550. The semiconductor device may be included in any one of the memory 510, the ASIC 520, the CPU 530, the FPGA 540, and/or the GPU 550.

The electronic device 500 may be a stand-alone system that uses the semiconductor device to perform one or more electrical functions. Alternatively, the electronic device 500 may be a subcomponent of a larger system. For example, the electronic device 500 may be part of a computer (e.g., a desktop computer, a laptop computer, or a tablet computer), a cellular phone (e.g., a smart phone), a personal digital assistant (PDA), a digital video camera (DVC), or other electronic communication device. Alternatively, the electronic device 500 may be the memory 510, the ASIC 520, the CPU 530, the FPGA 540, the GPU 550, a network interface card, or other signal processing card that can be inserted or included in a computer or other larger system.

The electronic device and/or the semiconductor device (e.g., FSFETs and/or GAA FETs) according to embodiments of the present disclosure may be incorporated or implemented in any suitable hardware, for example, a flexible printed circuit film, a tape carrier package (TCP), a printed circuit board (PCB), combinational logic, sequential logic, timers, counters, registers, state machines, volatile memories such as dynamic RAM (DRAM) and/or static RAM (SRAM), nonvolatile memory including flash memory (e.g., not-AND (NAND) flash memory), persistent memory such as cross-gridded nonvolatile memory, memory with bulk resistance change, phase change memory (PCM), and/or the like and/or any combination thereof, complex programmable logic devices (CPLDs), field programmable gate arrays (FPGAs), application-specific ICs (ASICs), central processing units (CPUs) including complex instruction set computer (CISC) processors and/or reduced instruction set computer (RISC) processors, graphics processing units (GPUs), neural processing units (NPUs), tensor processing units (TPUs), data processing units (DPUs). Also, a person of skill in the art should recognize that the electronic device and/or the FSFET may be combined or integrated into a single computing device, or the electronic device and/or the FSFETs may be distributed across one or more other computing devices without departing from the spirit and scope of the embodiments of the present disclosure. For instance, in some embodiments, the electronic device and/or the FSFET may be on one integrated circuit (IC) chip or on separate IC chips. In some embodiments, the electronic device and/or the FSFET may be implemented as a system-on-a-chip (SoC).

In some embodiments, the electronic device and/or the semiconductor device may be implemented entirely or partially with, and/or used in connection with, a server chassis, server rack, data room, data center, edge data center, mobile edge data center, and/or any combinations thereof.

The electronic device according to embodiments of the present disclosure may include a communication connection and/or a communication interface for communicating with one or more other devices via any suitable type of communication protocol. Examples include Peripheral Component Interconnect Express (PCIe), non-volatile memory express (NVMe), NVMe-over-fabric (NVMe-oF), Ethernet, Transmission Control Protocol/Internet Protocol (TCP/IP), Direct Memory Access (DMA) Remote DMA (RDMA), RDMA over Converged Ethernet (ROCE), FibreChannel, InfiniBand, SATA, SCSI, SAS, Internet Wide Area RDMA Protocol (iWARP), and/or a coherent protocol, such as Compute Express Link (CXL), CXL.mem, CXL.cache, CXL.IO and/or the like, Gen-Z, Open Coherent Accelerator Processor Interface (OpenCAPI), Cache Coherent Interconnect for Accelerators (CCIX), and/or the like, Advanced eXtensible Interface (AXI), any generation of wireless network including 2G, 3G, 4G, 5G, 6G, and/or the like, any generation of Wi-Fi, Bluetooth, near-field communication (NFC), and/or the like, or any combination thereof.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A semiconductor device comprising:
a first transistor comprising:
at least one first nanosheet channel region; and
a source region and a drain region at opposite ends of the at least one first nanosheet channel region;
a second transistor comprising:
at least one second nanosheet channel region; and
a source region and a drain region at opposite ends of the at least one second nanosheet channel region;
a common gate on the at least one first nanosheet channel region and the at least one second nanosheet channel region; and
a dielectric structure embedded in the common gate.

2. The semiconductor device of claim 1, wherein the at least one first nanosheet channel region comprising a plurality of first nanosheet channel regions stacked on each other.

3. The semiconductor device of claim 1, wherein the at least one second nanosheet channel region comprising a plurality of second nanosheet channel regions stacked on each other.

4. The semiconductor device of claim 1, wherein:
the dielectric structure has a threshold width;
the dielectric structure has a threshold vertical spacing distance from a lower end of the common gate; and
the dielectric structure has a threshold lateral spacing distance from the at least one first nanosheet channel region.

5. The semiconductor device of claim 4, wherein:
the threshold width is in a range from approximately 15 nm to approximately 30 nm;
the threshold vertical spacing is in a range from approximately 5 nm to approximately 75 nm; and
the threshold lateral spacing is in a range from approximately 10 nm to approximately 20 nm.

6. The semiconductor device of claim 1, wherein the dielectric structure comprises a at least one layer.

7. The semiconductor device of claim 1, wherein the first transistor is one of a forksheet transistor or a gate-all-around transistor.

8. The semiconductor device of claim 1, wherein the first transistor is one of a forksheet transistor or a gate-all-around transistor.

9. The semiconductor device of claim 1, wherein the dielectric structure comprises a dielectric material having a dielectric constant less than a threshold dielectric constant.

10. The semiconductor device of claim 9, wherein the threshold dielectric constant is approximately 5.

11. The semiconductor device of claim 9, wherein the dielectric material is selected from the group consisting of silicon dioxide (SiO₂), silicon nitride (SiN), silicon oxycarbonitride (SiOCN), silicon oxynitride (SiON), silicon nitride (SiCN), and a metal-organic framework (MOF).

12. The semiconductor device of claim 1, wherein the dielectric structure extends substantially entirely across the common gate.

13. The semiconductor device of claim 1, wherein the at least one first nanosheet channel region and the at least one second nanosheet channel region have a threshold width.

14. The semiconductor device of claim 1, further comprising:
a first dielectric wall, wherein the at least one first nanosheet channel region extends along the first dielectric wall; and
a second dielectric wall, wherein the at least one second nanosheet channel region extends along the second dielectric wall.

15. A method of manufacturing a semiconductor device, the method comprising:
etching a common gate electrode connecting a first transistor to a second transistor to form a trench in the common gate electrode; and
filling at least a portion of the trench with a dielectric material.

16. The method of claim 15, further comprising forming a mask on the common gate electrode.

17. The method of claim 15, wherein the first transistor is a first forksheet transistor.

18. The method of claim 15, wherein the first transistor is a first gate-all-around transistor.

19. The method of claim 15, wherein the dielectric material has a dielectric constant less than a threshold dielectric constant.

20. The method of claim 15, wherein the dielectric material is selected from the group consisting of silicon dioxide (SiO₂), silicon nitride (SiN), silicon oxycarbonitride (SiOCN), silicon oxynitride (SiON), silicon nitride (SiCN), and a metal-organic framework (MOF).
